(19) United States
(12) Patent Application Publication
(10) Pub. No.: US 2005/0184829 A1
(43) Pub. Date: Aug. 25, 2005

(54) LC composite component

(75) Inventors: Masahiro Yoshimoto, Miyazaki-shi (JP); Hiroshi Fujita, Miyazaki-gun (JP); Nobuaki Nagai, Miyazaki-gun (JP); Tokuji Nishino, Koyu-gun (JP); Shinichirou Kaneko, Fukuoka-shi (JP)

Correspondence Address: STEVENS DAVIS MILLER & MOSHER, LLP, 1615 L STREET, NW, SUITE 850, WASHINGTON, DC, 20036, US

(73) Assignee: MATSUSHITA ELECTRIC INDUSTRIAL CO., LTD., Osaka (JP)

(21) Appl. No.: 11/062,698

(22) Filed: Feb. 23, 2005

(30) Foreign Application Priority Data
Feb. 25, 2004 (JP) 2004-049664

(51) Int. Cl. H03H 7/01

(52) U.S. Cl. 333/185

(57) ABSTRACT

The LC composite component of the present invention comprises a base, a first to third terminals provided on the base, a helical conductor provided on the base, and an internal layer conductor inside the base, the internal layer conductor being opposed to the helical conductor provided on the base, each of the first to third terminals being mutually and electrically noncontinuous, the helical conductor being provided in either position between the first to third terminals. A high-pass filter is thus realized. The component can be used for various devices that require a reduction in size and cost of the electronic device while ensuring the filter performance.

### BACKGROUND OF THE INVENTION

The present invention relates to an LC (inductance and capacitance) composite component suited for an electronic device that performs radio communications such as mobile communication terminals and personal computers. Reference character L denotes an inductor component and C denotes a capacitor component.

In a cordless telephone and a mobile phone, miniaturization and reduction in the number of components are desired for a reduction in cost and miniaturization of mobile phones. The number of mobile electronic devices such as a notebook computer which uses data communications using a wireless LAN has been increasing. Miniaturization and reduction in the number of the components in these electronic devices are also desired.

An LC composite component is used as various kinds of filter circuits for the purpose of passing signals in a desired frequency band selectively and damping unwanted signals in a wireless communication circuit. There are many kinds of filters, such as a bandpass filter which passes a specific frequency band, a low-pass filter which passes only a low-frequency band, and a high-pass filter which passes only a high-frequency band.

Conventionally, in some cases, these filters are constructed by making an LC circuit on a substrate of a wireless device using an inductor component and a capacitor component which are individual chips. A composite component having a filtering function such as a dielectric filter, a surface elastic wave filter, and a laminated LC filter is used, and the laminated LC filter is often used for broadband.

FIG. 12 is a sectional view of a laminated LC filter according to a conventional technology as shown in JP-A-2000-341069. FIG. 13 is a perspective view of a laminated LC filter according to the conventional technology as shown in JP-A-1-259518.

However, a damping characteristic and a damping curve characteristic of the filter are determined by an equivalent circuit and the value of an inductor component L and a capacitor component C. The characteristic of the filter is made as desired by changing one of these values. In order to construct a filter used for GHz (gigahertz) bands, an impedance greater than a certain impedance is required. This requires a proper control of the inductor value or the capacitor value.

However, when a filter is constructed by laminated elements, the inductor component L is made by printing inside the laminated body, so that the value cannot be great. Thus, to gain a required damping characteristic the capacitor component must be increased. An improved material of the laminated body and an increase in the number of the layers of the laminated body is thus needed, which require an extra manhour and a cost. Therefore, there is a problem regarding limitations in the reduction of size and cost.

There is also a problem of the natural limitation of miniaturization of an element which is required to be downsized to a certain degree.

Further, the printing pattern which generates the inductor component is formed inside the laminated body and the printing pattern which generates the inductor component needs to be formed before firing the laminated body. Thus, there is a problem that the inductor value varies after the lamination, which realizes a difficulty in making a filter with high precision.

Also, an inductor component of a high-pass filter which passes a high-frequency band needs to be grounded. However, in a conventional method of a laminated body, via holes need to be provided on the laminated body, for example, to connect the inductor inside to the ground surface outside. This not only requires an extra process but also gives rise to a question in reliability.

An LC composite component such as a conventional laminated LC filter, as made clear in the sectional view in FIG. 12, comprises electrodes inside the ceramics, requiring a complex process. Thus, reduction in cost is difficult. A complex process and an increase in the number of processes include many factors of characteristic variation. In a connection with an external circuit, especially, circuit constants inside the filter cannot be finely adjusted for there is a need of matching a circuit pattern on the base and the impedance. Thus, an external matching circuit is additionally required. Therefore, miniaturization of the mobile terminal is difficult.

As made clear in the perspective view in FIG. 13, the pattern becomes large to acquire a great inductance value because the inductance is constructed in a plane. This is a problem when downsizing a component.

On the other hand, constructing the LC circuit with individual chips allows arbitrary constants and an increased degree of flexibility in substrate circuit design. However, the number of parts becomes many and the mounting area becomes large in comparison with a composite component. This gives rise to a difficulty in miniaturization of the substrate and the electronic device. The increased number of parts, as a matter of course, increases cost.

### SUMMARY OF THE INVENTION

An object of the present invention is to provide an LC composite component which can realize a reduction in size and cost of an electronic device such as a mobile terminal while ensuring a sufficient degree of flexibility in circuit substrate design used in wireless communication equipment.

An LC composite component of the present invention comprises a base, a first to third terminals provided on the base, a helical conductor provided on the base, and an internal layer conductor inside the base, the internal layer conductor being opposed to the helical conductor provided on the base, each of the first to third terminals being mutually and electrically noncontinuous, the helical conductor being provided in either position between the first to third terminals.

With the construction of the present invention, the contribution of a capacitor component C to a determination of the filter characteristic is greater than the contribution of an inductor component L. Thus, it is possible to realize a desirable filter characteristic while pursuing a reduction in size and cost. In particular, there is no need of increasing the number of layers of the laminated body or considering expensive materials, which inhibits a reduction in size and cost.

A helical conductor formed by trimming a part of the base covered with a conductive film is an inductor component, gaps provided over the periphery of the conductor compose a coupling capacitor component between gaps, an area between the helical conductor and an internal layer electrode compose a coupling capacitor component coupled by an insulation layer. Thus, in an equivalent circuit, “an LC composite circuit,” in which the inductor component L and the capacitor component C are connected, is constructed.

Further, the helical conductor is provided outside the base, and a terminal connected to the helical conductor is also provided outside. Thus, an equivalent circuit as a circuit when the inductor component is connected to the ground is realized. A high-pass filter which is expensive in lamination type is easily constructed.

In particular, an internal layer conductor which generates a capacitor component parallel with the helical conductor which generates the inductor component is provided and realized inside the base, and the equivalent circuit as the high-pass filter is realized. The helical conductor which is the inductor component and the gaps which compose the capacitor component are formed by trimming in which the precision is high and the number of processes is less. The LC composite component in which a yield is enhanced and the cost is reduced is attained. The reliability of the component is also very high.

As a matter of course, trimming enables to form the helical conductor with very fine adjustments. Therefore, the inductor component and the capacitor component with very high precision are formed in one element.

The circuit constant is set by trimming the base covered with the conductive film. This enables setting the constant according to the substrate pattern of a wireless device with fine adjustments. Reduction in the number of parts of the wireless device, reduction in cost, and reduction in the mounting area are realized and the LC composite component can easily conform to the form of the electronic device and performance specifications.

The inductor component can be constructed in 3D in a helical form which enables acquiring great inductor value easily. Miniaturization of the component and reduction in the mounting area are realized and the LC composite component can easily conform to the form of the electronic device and performance specifications.

Also, the LC composite component which has no mounting direction can also be provided by locating the helical conductor to become a symmetrical circuit with respect to an input and output of signals.

Adjustments of the inductor component by forming the inside independent conductor apart from the internal layer conductor enable to enhance the degree of flexibility in forming a pole in the damping characteristic of the filter. The damping characteristic is thus easily enhanced.

### BRIEF DESCRIPTION OF THE DRAWINGS

FIG. 1(a) is a perspective view showing an LC composite component according to a first embodiment of the present invention, and FIG. 1(b) is a sectional view of the LC composite component according to the first embodiment of the invention.

FIG. 2 is a perspective view showing the LC composite component according to the first embodiment of the invention.

FIG. 3 is a perspective view showing the LC composite component according to the first embodiment of the invention.

FIG. 4 is a perspective view showing the LC composite component according to the first embodiment of the invention.

FIG. 5 is a diagram showing an equivalent circuit of the LC composite component according to the first embodiment of the invention.

FIG. 6 is a diagram showing an equivalent circuit of the LC composite component according to the first embodiment of the invention.

FIG. 7 is a diagram showing an equivalent circuit of the LC composite component according to the first embodiment of the invention.

FIG. 8 is a graph showing a simulation result of the first embodiment of the invention.

FIG. 9 is a view showing a manufacturing method of the LC composite component according to a second embodiment of the invention.

FIG. 10 is a view showing the manufacturing method of the LC composite component according to the second embodiment of the invention.

FIG. 11 is a schematic view showing a part of an electronic circuit according to a third embodiment of the invention.

FIG. 12 is a sectional view showing a laminated LC filter according to a conventional technology.

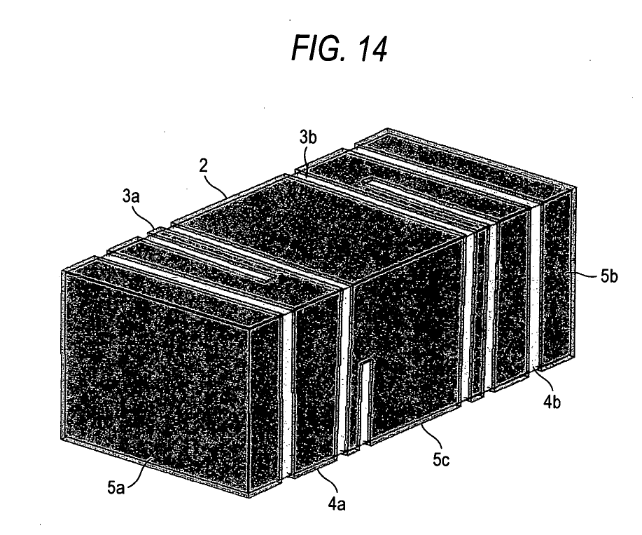

FIG. 13 is a perspective view showing the laminated LC filter according to the conventional technology.

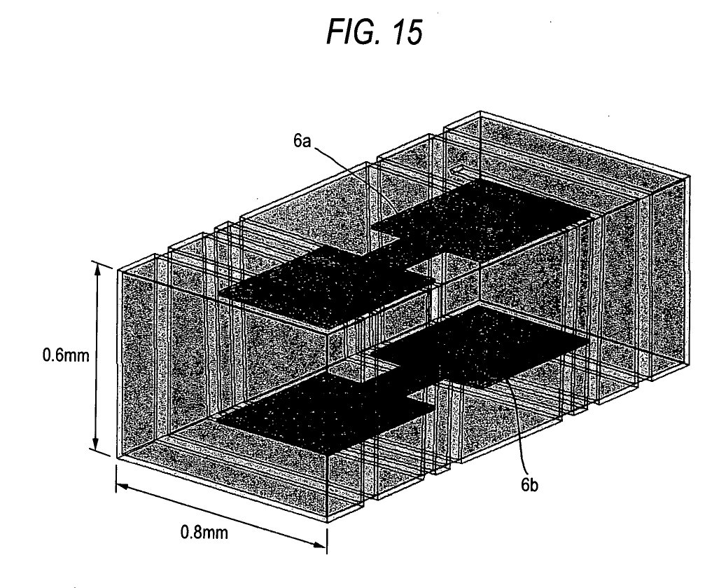

FIG. 14 is a perspective view showing the LC composite component according to the fourth embodiment of the invention.

FIG. 15 is a perspective view showing inner pattern of the LC composite component according to the fourth embodiment of the invention.

FIG. 16 is a perspective view showing the LC composite component according to the fourth embodiment of the invention.

FIGS. 17, 18, and 19 show a manufacturing method of the LC composite component according to the invention.

### DETAILED DESCRIPTION FO THE PREFERRED EMBODIMENTS

In the following, preferred embodiments will be explained accompanied with drawings.

### First Embodiment

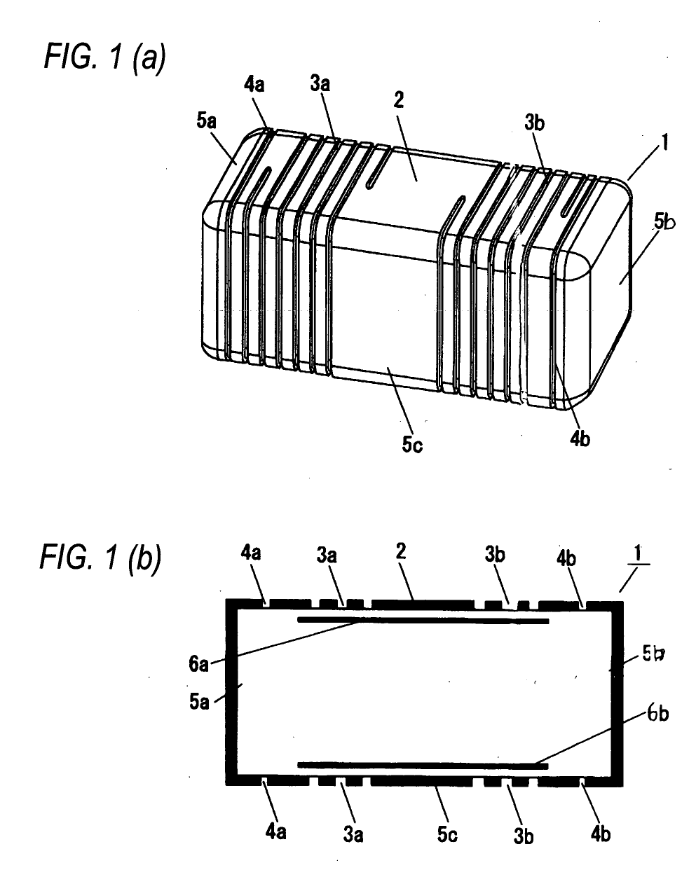

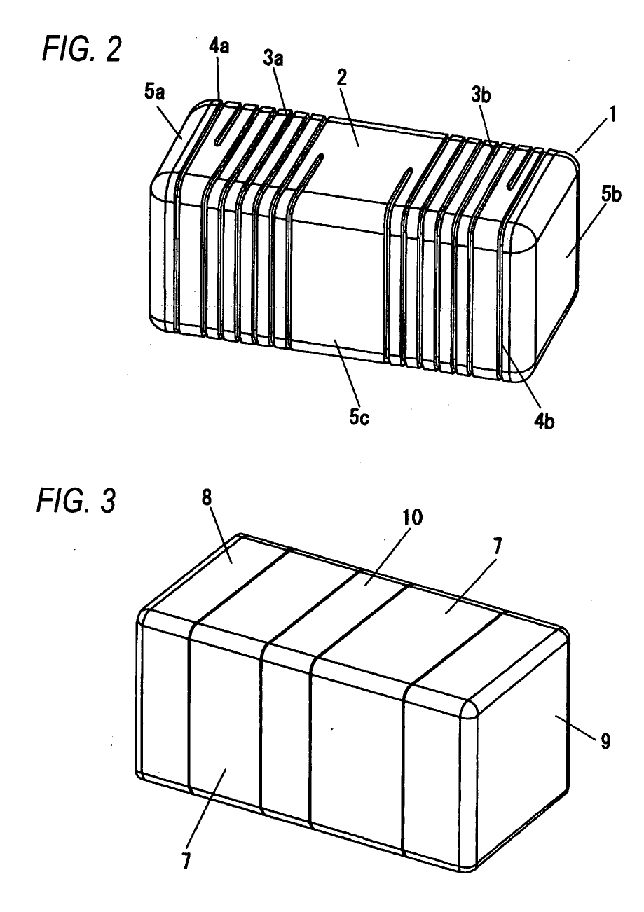

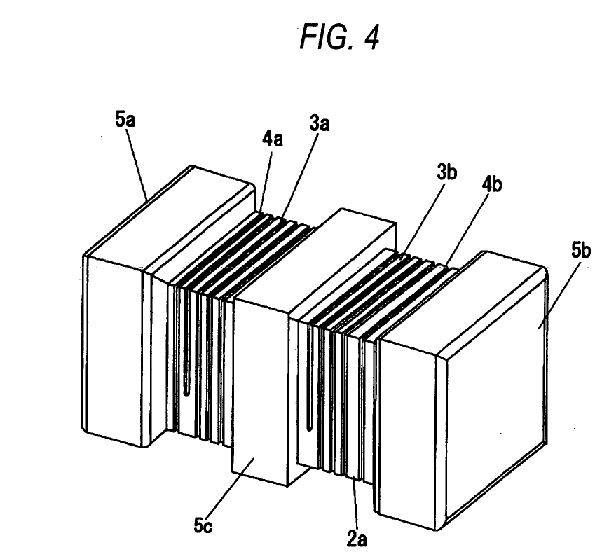

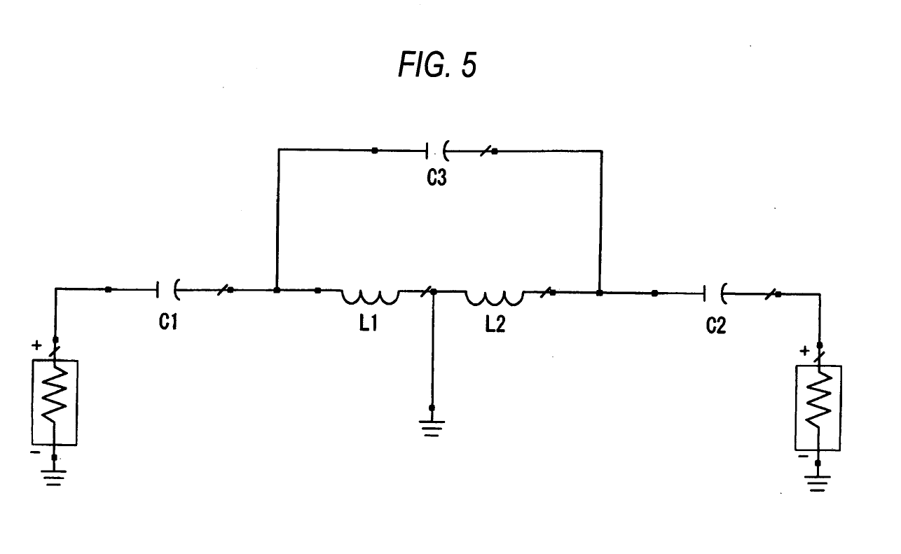

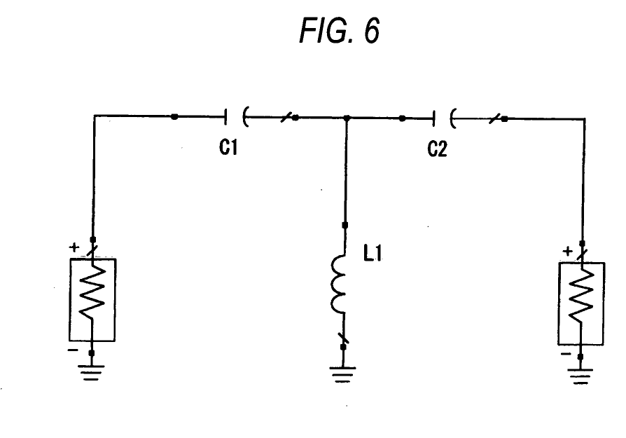

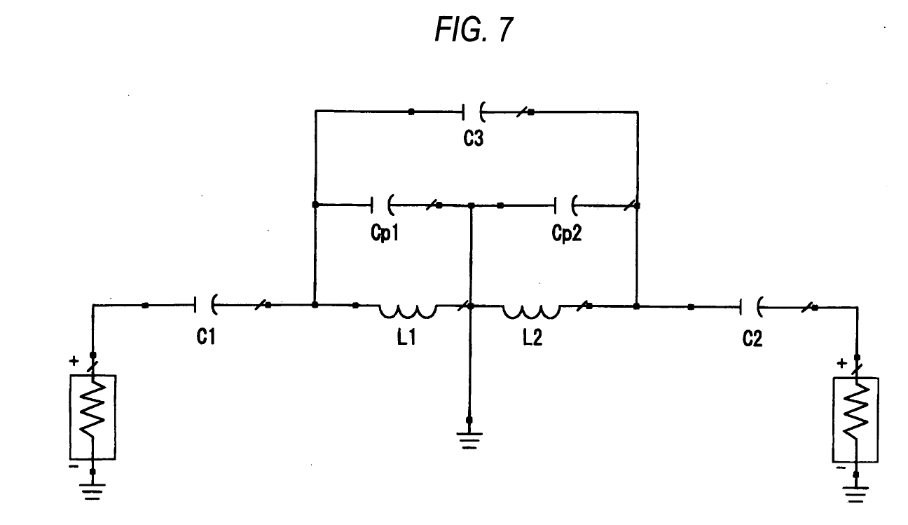

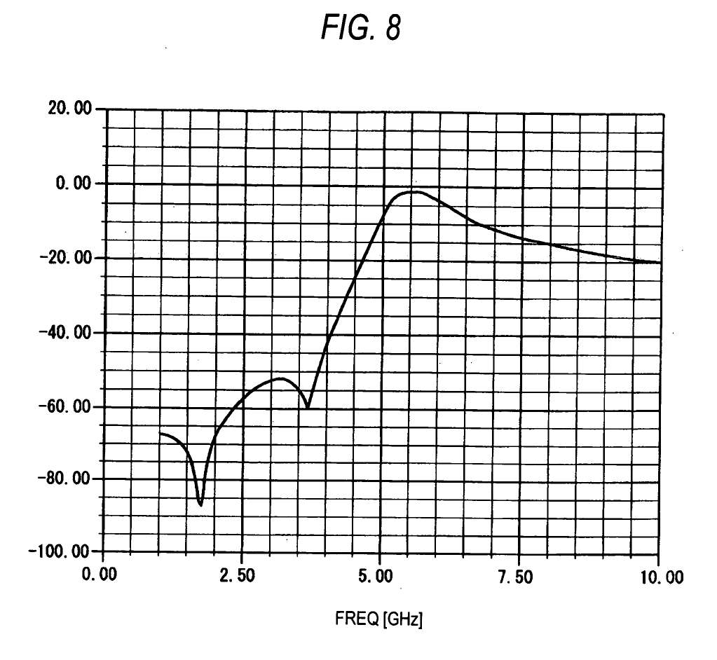

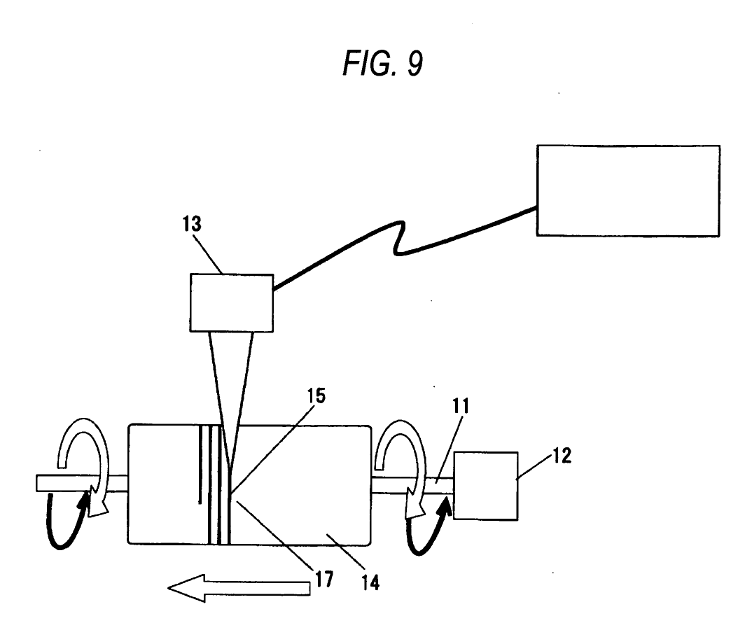

FIG. 1(a) is a perspective view of an LC composite component according to a first embodiment of the present invention. FIG. 1(b) is a sectional view of the LC composite component according to the first embodiment of the invention. FIG. 2, FIG. 3, and FIG. 4 are perspective views of the LC composite component according to the first embodiment of the invention. FIG. 5, FIG. 6, and FIG. 7 are diagrams showing equivalent circuits of the LC composite component according to the first embodiment of the invention. FIG. 8 is a view showing a simulation result according to the first embodiment of the invention.

Reference Numeral 1 denotes the LC composite component; 2, a base; 3a and 3b, helical conductors; 4a and 4b, gaps; 5a, a first terminal; 5b, a second terminal; 5c, a third terminal; 6a and 6b, internal layer conductors; 7, a protective film; and 8, 9, and 10, connection films, respectively.

Reference symbols C1, C2, C3, CP1, and CP2 denote capacitor components and L1 and L2 denote inductor components.

Each part of the LC composite component is described in detail using FIG. 1(a), FIG. 1(b), and FIG. 2.

First, the base 2 will be described in the following.

The base 2 is made of a material having an insulation property. Barium titanate, alumina, a material containing alumina as the main ingredient, forsterite, magnetic ferrite, and silicon oxide are suited for the material of the base 2. In particular, a large capacitor is attained by using a dielectric material containing barium titanate which has a large dielectric constant as the main ingredient. An electronic component which conforms to a high frequency is acquired by using alumina or the material containing alumina as the main ingredient. The material also has a high strength and is processed easily.

One or more conductive films made of a conductive material such as copper, silver, gold, and nickel, are laminated on the whole of the base 2, including ends, sides, and all-around side, and conductive surfaces are formed. To form the conductive films, plating, vapor deposition, sputtering, pasting, chemical vapor deposition, and printing are used. The dielectric constant of the ceramics used as the base material is desirably about 1 to 150. Thereby, the conductive films which make the whole surface of the base 2 electrically continuous is formed. The base 2 made of the dielectric material such as alumina thus has the capacitor component as a whole.

In addition, the conductive film may be formed except end faces as will be described later.

Whereas the base 2 is illustrated as a square pole in FIG. 1(a), the base 2 may also be a cylinder or a polygon pole for which the bottom is an n-sided polygon, where n is five or more. Or the base 2 may be a triangle pole.

Next, the internal layer conductors 6a and 6b will be described since they relate to the forming of the base 2.

The internal layer conductors 6a and 6b are made of platinum, tungsten, palladium, copper, gold, nickel, silver, an alloy of these, or another metallic plate, or formed by pasting or a pattern. The internal layer conductors 6a and 6b are formed inside the base 2. The internal layer conductors 6a and 6b are positioned to oppose the helical conductors 3a and 3b formed on the two surfaces of the base 2 which surfaces are opposed to each other, as shown in FIG. 1(b).

A capacitor coupling needs to be generated between the internal layer conductors and the helical conductors 3a and 3b, as will be described later. So the distance between the internal layer conductors 6a and 6b and the opposed surfaces of the base 2 (i.e., the opposed helical conductors 3a and 3b) is preferably a distance that enables the capacitor coupling and generates the capacitor component corresponding to a desired filter characteristic.

To generate the capacitor coupling more properly, the plane that the helical conductors 3a and 3b form, i.e., the surface of the base 2 which surface opposes the internal layer conductors 6a and 6b, which is about parallel with the internal layer conductors 6a and 6b is preferable. This has an advantage that the capacitor component to be generated does not become imbalanced in each area.

One way of forming the internal layer conductors 6a and 6b is that first the material of the base 2 is molded into a sheet shape by slip casting, and the pattern of the internal layer conductors 6a and 6b is formed on a part of the sheet by screen printing. (As a matter of course, a metal film may be formed or the internal layer conductors 6a and 6b may be formed on the sheet by a metal plate or metal pasting.) Platinum paste and tungsten paste are used as a conductive paste for the printing for a high-temperature sintered material such as alumina, and oxidation and diffusion are thus inhibited when sintering. Silver or copper paste may be used for a low-temperature sintered material such as glass ceramics. It is also possible to form the internal layer conductors 6a and 6b shown in FIG. 1(b) by firing after laminating sheets with the pattern and sheets without the pattern.

Because the internal layer conductors 6a and 6b are thus formed, the internal layer conductors 6a and 6b are not electrically continuous with the conductive film on the surface of the base 2, the first terminal 5a nor the second terminal 5b.

The helical conductors 3a and 3b will next be described.

The helical conductors 3a and 3b are provided over the all-around periphery of the base, forming the inductance component. The inductance value can be adjusted by adjusting, for example, the number of turns, the groove width, and the groove depth of the helical conductors 3a and 3b. The helical conductors 3a and 3b are formed between the gaps and the third terminal 5c. As shown in FIG. 1, the helical conductors 3a and 3b may be formed between the third terminal 5c and each of the first and second terminals 5a and 5b, or may be formed in only one of the areas between the first and second terminals 5a and 5b and the third terminal 5c. Also, when the helical conductors 3a and 3b are formed in both areas between the first and second terminals 5a and 5b and the third terminal 5c, a mounting direction of the LC composite component can be eliminated by locating the helical conductors 3a and 3b symmetrically with reference to the third terminal 5c so that the circuit becomes symmetric with a center of the third terminal 5c. With no mounting direction, the filter works as having the same characteristic which will be described later even the filter is mounted in any direction. A mounting error will thus be eliminated. As a result, improvement in yield and reduction in cost are realized. When the helical conductors are constructed symmetrically, although FIG. 1 shows the two helical conductors disposed in 180-degree rotational symmetrical positions with reference to the third terminal 5c, the two helical conductors may be disposed in 180-degree mirror symmetrical positions with reference to the third terminal 5c as shown in FIG. 2. This can adjust the coupling power of the magnetic coupling between the inductances by varying the mutual direction of the magnetic directions of the inductance components generated by the helical conductors 3a and 3b.

Two or more helical conductors may be provided between the gaps 4a and 4b and the third terminal instead of one helical conductor.

Next, the gaps 4a and 4b will be described.

One pair of the gaps 4a and 4b is provided on the base 2. Each of the gaps 4a and 4b is formed by partitioning the whole side surface of the base 2 entirely and peeling off the conductive film. On the base 2, the vicinity of the center, in which the helical conductors 3a and 3b exist, and the conductive film are partitioned by the gaps 4a and 4b. An electrically noncontinuous state is produced. The gaps 4a and 4b generate the coupling capacitor with opposed surfaces, forming capacitor components. In other words, the capacitor components between the first terminal 5a and the second terminal 5b and the surfaces opposed to the terminals 5a and 5b can be formed. Incidentally, the first terminal 5a and the second terminal 5b are formed as a pair on the base 2.

The capacitor value is adjustable by adjusting the groove width of the gaps. It is possible to form the capacitor component in accordance with a use.

Because the gaps 4a and 4b are made to form the first terminal 5a and the second terminal 5b as a pair of terminals, it is preferable to provide them in positions near the both ends of the base 2 in terms of ease in manufacturing. However, in response to the convenience of the areas allocated for the first terminal 5a and the second terminal 5b and of the capacitor component value, the gaps 4a and 4b may be formed in positions nearer to the center, as a matter of course.

The gaps 4a and 4b for forming the first terminal 5a, the second terminal 5b, and the third terminal 5c are formed by trimming the conductive film covering the base 2 with a laser or a grinding wheel. The capacitor component generated between the opposed surfaces can be adjusted by adjusting the groove width and the groove depth appropriately. Thus, it is suitable to adjust them appropriately.

Instead of laser trimming, a resist may be formed on the conductive film formed on nearly the entire surface by photolithography, and the gaps may be formed by etching.

The gaps are those which are provided to form the first terminal 5a and the second terminal 5b and to generate the coupling capacitor in each terminal, thus they may not be called gaps but grooves, trenches, cuts, strips, incisions, or the like.

Next, the first and second terminals 5a and 5b and the third terminal 5c will be described.

The first terminal 5a to the third terminal 5c are mutually and electrically noncontinuous.

The first terminal 5a to the third terminal 5c are the designations to express clearly in the specification and the claims. The numbers first to third are not a requirement for the construction. They can be transposed or they can have other designations.

The first terminal 5a, the second terminal 5b, and the third terminal 5c are constructed by forming the gaps 4a and 4b provided on the conductive film, which covers the base 2, by trimming as described above. Further, the first terminal 5a, the second terminal 5b, and the third terminal 5c are constructed with the conductive film made of a dielectric material.

The terminals may be formed by making the gaps on the conductive film which is formed on the whole base 2. It is realized by forming the conductive film, which in advance avoids the gaps on the surface of the base 2 provided with the gaps, also on the surfaces of the first terminal 5a, the second terminal 5b, and the third terminal 5c. Alternatively, a conductive film with more layers may be formed for the conductive characteristic and a strength adjustment. Another conductive film material or another layer construction may be applicable distinct from the surface of the base 2 with the helical conductors 3a and 3b.

It is common that the first terminal 5a and the second terminal 5b constitute a pair of terminals provided on the base 2 and formed at the both ends. However, when there exists a bump at the ends, for example, the terminals may not be provided at the both ends. The terminals may be formed at some midpoint or they may be formed in asymmetrical positions instead of symmetrical positions to each other.

The first terminal 5a and the second terminal 5b are mounted on the base so that the plating layer structure which has a high affinity for a mounting land is also suitable.

The first terminal 5a and the second terminal 5b are preferably provided on the end surface of the base 2 and the side of the base 1, respectively. However, the conductive film may not be formed on the end surface and the terminals may be provided only on the side of the base 2. Or the terminals may be only on a part of a side of the sides.

The third terminal 5c is preferably provided at a midpoint of the base 2 and between the first terminal 5a and the second terminal 5b. However, the terminals may be provided about the center of the base 2. This has an advantage of ensuring left-right symmetry of the LC composite component 1. As a matter of course, however, the terminals may be positioned at a deviated place from the center to the left or the right.

The first terminal 5a, the second terminal 5b, and the third terminal 5c are mounted on the mounted substrate. The terminals are formed, for example, by soldering to the mounting land provided on the mounted substrate.

The first terminal 5a and the second terminal 5b as a pair are mounted at a signal line on the mounted substrate, and an electric signal is inputted and outputted. On the other hand, the third terminal 5c is connected to the grounding part to realize an equivalent circuit which will be described later as shown in FIG. 5 and FIG. 6, and the high-pass filter is realized.

Other cases of different shapes will be described next with FIG. 3 and FIG. 4.

FIG. 3 shows the LC composite component on which the protective film 7 is formed. FIG. 4 shows the case when the base 2 has a layer down over all around except the first terminal 5a, the second terminal 5b, and the third terminal 5c.

First, the protective film 7 will be described.

The protective film 7 is provided to cover at least the helical conductors 3a and 3b and the gaps 4a and 4b. The protective film 7 may be provided all around the base 2 except the first to third terminals 5a to 5c, as a matter of course. The protective film 7 is made of an insulating material. Resin and ceramic are suitable. Concretely, a resin material such as epoxy resin and insulating film such as silicon oxide are mentioned.

The protective film 7 is formed by various kinds of methods such as coating, electrodeposition, and electrostatic coating. The film may be formed with a protective film in a tube shape. The protective film in the tube shape is made by placing the protective film in the tube shape around the base 2 and crimping the film by adding heat. The protective film in the tube shape is formed to cover the helical conductors and the gaps. Thus, the protective film does not flow into the grooves of the helical conductors 3a and 3b and the gaps 4a and 4b. This is an advantage because the helical conductor characteristics, i.e., the inductor characteristic, does not vary when the protective film in the tube shape is provided. A material made of resin, especially with a heat contraction property, is preferably used for the protective film in the tube shape. This is because the tube shrinks when the protective film in the tube shape is caused to cover the base 2 and is processed with heat treatment, and the protective film in the tube shape is formed on the base 2 with reliability.

The coating material is preferably either of electrodeposition coating, transfer coating, glass, or low-temperature sintered ceramics, or a combination thereof.

The protective film 7 prevents the conductive film on the base 2 from damage and prevents the grooves of the helical conductors 3a and 3b and the gaps 4a and 4b from damage. They can be especially protected from an impact and heat in transportation and mounting.

The connection films 8, 9, and 10 are constructed with so called lead-free solder which is simplex Sn or Sn added with an element other than lead. In the present embodiment, the connection films 8, 9, and 10 are provided in order to enhance a junction property when mounted on the circuit board, though, the connection films 8, 9, and 10 are unnecessary when it is sufficient with the first terminal 5a, the second terminal 5b, and the third terminal 5c. More preferably, a film of nickel or an alloy of nickel is provided between the first terminal 5a, the second terminal 5b, the third terminal 5c and the connection films 8, 9, and 10 to inhibit solder corrosion and enhance weather resistance of the first terminal 5a, the second terminal 5b, and the third terminal 5c.

It is also preferable to provide a layer down over all around the base 2 except the first terminal 5a, the second terminal 5b, and the third terminal 5c as shown in FIG. 4. With the layer down, the circuit substrate does not contact directly to the helical conductors 3a and 3b at mounting. Hence, there is no influence on the characteristics. When the protective film 7 is provided, the height of the protective film 7 can be almost the same as the height of the first to third terminals 5a to 5c. A malfunction of mounting of the first terminal 5a, the second terminal 5b, and the third terminal 5c does not occur at mounting. Thus, a problem such as a tombstone phenomenon does not occur. Further, the protective film 7 can be formed to be thick to enhance the weather resistance of the helical conductors 3a and 3b. Even with the layer down, it has the same effect as that of the construction shown in FIG. 1 and FIG. 2, as a matter of course.

Next, an operation mechanism of the LC composite component with the above construction is described.

The high-pass filter characteristic appears with the inductor component and the capacitor component generated in the helical conductors 3a and 3b and the first terminal 5a and the second terminal 5b in the construction described above. In other words, let the inductor value of the helical conductor 3a be L1, the inductor value of the helical conductor 3b be L2, the coupling capacitor values of the first terminal 5a and the second terminal 5b be C1 and C2, respectively, the coupling capacitor value between the internal layer conductors 6a and 6b and the helical conductors 3a and 3b be C3 in FIG. 1. This becomes the equivalent circuit of the high-pass filter shown in FIG. 5.

The equivalent circuit shown in FIG. 6 has the high-pass filter characteristic passing only a high-frequency band. That the inductor component L1 is connected to the ground and C1 and C2 which are parallel with L1 are connected to each other is the basic circuit construction having the high-pass filter characteristic. It is significantly troublesome to form the circuit construction like this with elements of a lamination type according to the conventional technology.

C3, L1, and L2 in FIG. 5 are converted to an equivalent circuit shown in FIG. 6 by Y-Δ(delta) transformation. The circuit in FIG. 6 is the equivalent circuit realized by the construction of the present invention shown in FIG. 1 to FIG. 4 as described above. As a result, the equivalent circuit in FIG. 5 for which a circuit works as the high-pass filter is constructed.

The circuit in FIG. 6 is known as a T circuit. An impedance Z of the inductor component is calculated in equation (1) and an impedance Z of the capacitor component is calculated in equation (2). The inductance component becomes a high impedance and the capacitor component becomes a low impedance as the frequency becomes high. A signal with a high frequency is easy to flow, thus the circuit has the high-pass characteristic.

$$\begin{matrix}Z = ω L & ( 1 ) \\ Z = \frac{1}{ω C} & ( 2 )\end{matrix}$$

The LC composite circuit 1 is mounted at the signal line. When a signal is inputted from one of the first terminal 5a and the second terminal 5b and the signal is outputted from the other terminal, the circuit works as the high-pass filter passing only signals in a certain frequency band.

A signal in a low frequency less than the passing band is eliminated with reliability by connecting the third terminal 5c to the ground.

Further, not only do the helical conductors 3a and 3b have the inductance component but also the coupling of the electric field between the helical lines generates the capacitances Cp1 and Cp2 disposed parallel with the inductance in the equivalent circuit as parasitic capacitors as shown in FIG. 7. The inputted signal is separated into the signal which passes the capacitance Cp1 and the signal which passes the inductance L1. A phase of the signal passing the path through the inductance varies 90 degrees. A phase of the signal passing the path through the capacitance varies −90 degrees. The signals have 180-degree opposite phases when they are combined. The signal becomes zero at a resonance frequency fr1 of a parallel resonance circuit with Cp1 and L1. The resonance frequency fr1 is calculated from a resonance condition (3). The signal which passes capacitance Cp2 and the signal which passes the inductance L2 become zero at a resonance frequency fr2 of a parallel resonance circuit with Cp2 and L2. Thus, the filter has the damping characteristic which has poles at the frequencies fr1 and fr2.

$${f}_{0} = \frac{1}{2 π \sqrt{LC}} \qquad ( 3 )$$

A result of an experiment in which the LC composite component 1 is used as the high-pass filter is shown in FIG. 8. The experiment is carried out under the conditions of the equivalent circuit shown in FIG. 7. The LC composite component works as the high-pass filter which passes a signal in a frequency band more than 5 GHz as made clear in FIG. 8. There are poles at 2 GHz and 4 GHz, and the slope of the decay curve is sufficiently steep, proving the high quality of the high-pass filter. The poles are realized by the capacitors Cp1 and Cp2 generated between the grooves of the helical conductors 3a and 3b.

A magnetic flux developed by the helical conductors 3a and 3b can be reduced by forming an independent internal layer conductor other than the internal layer conductors 6a and 6b for which an independent internal layer conductor is independent and isolated inside the base, although this is not shown in the drawings. Thus, the cutoff characteristic of the filter can be changed by adjusting L1 and L2 of the equivalent circuit in FIG. 5 to vary a position at which the pole is developed. Furthermore, there is a great advantage of enhancement of the filter characteristic that the frequency of pole development can be varied without changing the cutoff frequency as the filter characteristic because of the existence of the capacitor components Cp1 and Cp2 which are generated parallel with the inductor component.

The cutoff frequency of the high-pass filter can be varied because the inductance values L1 and L2 and the capacitor values C1, C2, and C3 can be numerically adjusted. This can be realized by changing the groove width or the groove depth of the helical conductors 3a and 3b and the gaps 4a and 4b or the size, the area, or the material of the internal layer conductors 6a and 6b appropriately.

In a conventional technology, size 1608 of a laminated LC filter is the smallest size as an LC composite component. However, in the present embodiment, in size 1005 or furthermore in size 0603, the inductance of 1 to 56 nH can be attained at the helical conductors, and the capacitance of the gaps can be 0.1 to 10 pF with the gaps of which the width is 0.01 to 0.1 mm by using ceramics having a dielectric constant of 1 to 150 for the material of the base, so that the LC composite component of ultra-compact size 0603 can be realized. Thus, the filter can be constructed with a very small component compared with the conventional laminated LC filter. Miniaturization of the component leads to a reduction in the mounting area, which enables the electronic device comprising the component to be reduced in size as a whole.

Another element size can be used similarly, as a matter of course.

Numerical adjustments are very easy compared with the LC composite component of the lamination type in which a lamination part is used as a capacitor component after inductors are constructed inside the lamination, because the capacitor value and the inductor value of the present invention are determined by trimming. Both of the inductor value and the capacitor value can be determined simultaneously by the process of trimming. This means that the inductor and the capacitor can be formed in similar kinds of operations, simplifying the process compared with the LC composite component of the lamination type which needs a complex process of lamination after forming the inductors by transfer or printing. The simplified process inhibits variations and reduces cost.

Because the precise means of trimming is used, a component with high precision is attained. Enhanced yield and reduction in cost are easily realized since variations in the capacitor value and the inductor value caused inevitably during lamination are reduced. The coupling capacitor of the gap 4a can be used as the capacitor component so that determination and fine adjustments of the capacitor component becomes easy.

An LC composite component such as a filter needs a certain impedance to ensure the filter characteristic sufficiently. The impedance is determined by the appropriate value of the capacitor component or the inductor component. Conventionally, an adjustment of the capacitor component is considered important in the element of the lamination type, resulting in increase in size, low precision, and high cost.

The present invention realized the LC composite component by focusing attention on the inductor component, not the capacitor component. In other words, by forming the conductor film on the surface of the base 2 and forming the helical conductors 3a and 3b on the film, a sufficient inductor value is obtained. Thus, avoidance of an increase in size and high cost which is inevitable for ensuring the capacitor value in the lamination type is easily attained.

Moreover, the element does not become large , however, it can be reduced in size. Cost reduction is attained because it is unnecessary to select an expensive material to increase the capacitor component. These are advantages that the component has. In the conventional element of the lamination type, it is significantly troublesome to make the equivalent circuit in FIG. 6 for which the circuit realizes a high-pass filter. However, the construction that the internal layer conductors 6a and 6b are positioned to oppose the helical conductors 3a and 3b to realize the equivalent circuit shown in FIG. 5 is one of the steps to realize the equivalent circuit in FIG. 6.

In addition, enhancement of performance which is difficult in the lamination type is attained by paying attention to that the frequency of the pole development is easily changed by providing the independent internal layer conductor to dampen the magnetic flux density easily without changing the pass frequency.

As described above, the LC composite component with high yield, low cost, very compact size, and high precision is obtained. The high-pass filter which passes only a high frequency band is also obtained.

### Second Embodiment

A method of construction of the LC composite component will be described next.

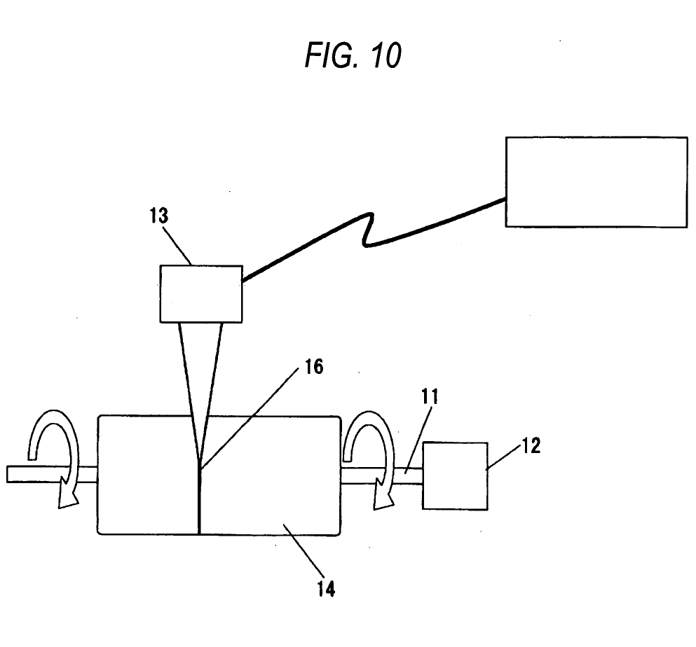

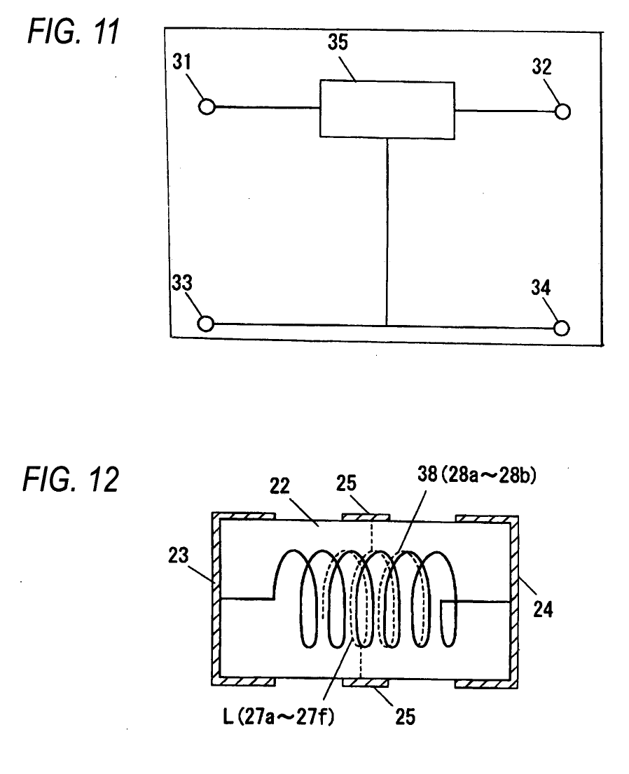

FIG. 9 and FIG. 10 show the method of construction of the LC composite component according to a second embodiment of the present invention.

Reference Numeral 11 denotes a rotational support; 12, a motor; 13, a laser irradiation device; 14, a base with a conductive film; and 15, a helical groove. The base with the conductive film 14 is formed by stamping or extruding a dielectric material or insulation such as alumina or a ceramic material containing alumina as the main ingredient, as described in the first embodiment. The conductive film of the base 14 with the conductive film is formed by laminating one or more conductive films made of a dielectric material such as copper, silver, gold, or nickel.

As shown in FIG. 9, the base 14 with the conductive film is provided on the rotational support 11, rotated by the motor 12, and irradiated with a laser beam from the laser irradiation device 13 while at least one of the laser irradiation device 13 and the rotational support 11 is moved to form the helical groove 15. At this time, the helical groove 15 is excavated beyond the conductive film positively to leave the conductive film in a helical shape. Thus, the helical conductors 3a and 3b having the conductive film in the helical shape are formed. A plurality of helical conductors may be formed in mirror symmetrical positions by rotating the motor 12 backward.

As shown in FIG. 10, the base 14 with the conductive film is provided on the rotational support 11, rotated by the motor 12, and irradiated with a laser beam from the laser irradiation device 1 to form the gap grooves 4a and 4b.

A plurality of helical conductors and gaps can be constructed on the same base by a program control that controls an on-off action of the laser irradiation, the rotation of the motor, and the movement of at least one of the laser irradiation device 13 and the rotational support 1, for which operations are shown in FIG. 9 and FIG. 10.

The conductor 17 in which the helical groove 15 is not formed on the base 14 with the conductive film is formed by halting the laser irradiation from the laser irradiation device 13 after the helical groove 15 is formed along a certain width. By repeating this as many times as desirable, a plurality of the helical grooves 15 comprising the helical groove 15 and a plurality of conductors 17 are formed alternately. Incidentally, a cutting process with a grinding wheel or the like may be used instead of the laser irradiation. When forming the helical conductor at only one place, as a matter of course, the laser irradiation is performed at the one place, and the laser irradiation is completed.

### Embodiment 3

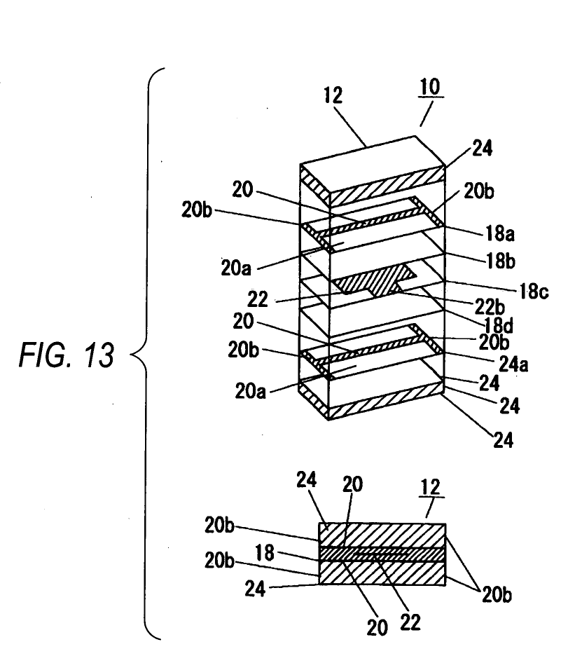

FIG. 11 is a schematic view of a part of an electronic circuit according to a third embodiment of the present invention. It is a part of various kinds of electronic circuits of an electronic device such as a wireless terminal. Reference Numerals 31 and 32 denote signal lines, and Reference Numerals 33 and 34 denote grounding lines. Reference Numeral 35 denotes an LC composite component according to the present invention. In FIG. 11, the first terminal 5a and the second terminal 5b of the LC composite component 35 are connected to the signal lines 31 and 32. A circuit, in which a signal inputted from the signal line 31 is filtered with a filter having a center frequency of a pass band which is the resonance frequency of the LC composite component of the invention and the filtered signal is outputted to the signal line 32, can be constructed. The third terminal 5c is connected to the grounding lines 33 and 34 to establish a short circuit to the ground for unnecessary signals.

FIG. 11 shows the case when the LC composite component described at the first and the second embodiments is connected to a mounted substrate of some kind. Glass epoxy resin, a ceramic base, and a flexible printed board are preferably used as the mounted substrate 100. The embodiment shows the mounted substrate 100 as a rectangle, however, it may be a circle or an ellipse. The mounted substrate 100 may be constructed to provide one or more elements of at least one of wiring, a capacitor, and an inductor inside the mounted substrate, although not shown in the figure. That is, a multilayered base may be used as the mounted substrate 100.

Since this kind of circuit is mounted, the component can be used as the high-pass filter for noise removal or frequency selection. In this case, because the LC composite component 35 can be constructed as a very small element, the electronic circuit is also reduced in size. An electronic device incorporating the electronic circuit is thus downsized. The LC composite component realizes high yield and low cost so that low cost of the electronic device is also realized. It also realizes reduction in operation failures after mounting, which enhances the reliability of the electronic device.

### Fourth Embodiment

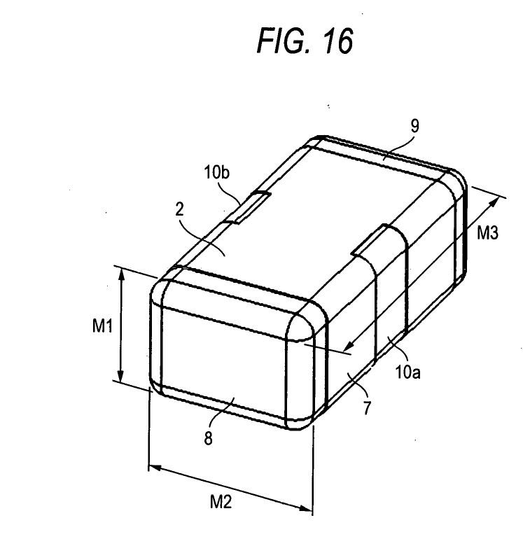

Next, fourth embodiment will be described with FIG. 14 to FIG. 16.

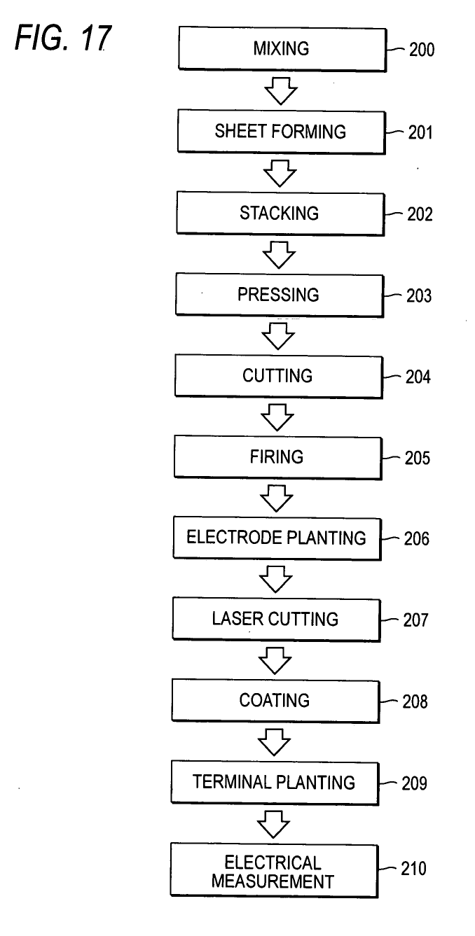

In FIG. 14, the first terminal 5a and the second terminal 5b are provided at both ends of the base 2, respectively, and the third terminal 5c is provided between the first terminal 5a and the second terminal 5b. Furthermore, the third terminal 5c is provided separately from the first terminal 5a by the gap 4a and is provided separately from the second terminal 5b by the gap 4b. Spiral conductors 3a and 3b are provided at the both ends of the third terminal 5c, and the third terminal 5c and the spiral conductors 3a and 3b are integrated. Functions and materials are almost the same as those shown in FIG. 1. A pair of internal layer conductors 6a and 6b are provided in the base 2 as shown in FIG. 15. The internal layer conductors 6a and 6b are opposed to each other, and the internal layer conductors 6a and 6b are an array shape in which the center is narrow. The shape of the internal layer conductors 6a and 6b are described in other words as a shape in which the center of the rectangular conductor is narrow. Usually, in the state where the internal layer conductors 6a and 6b in the rectangular shape are left inside the base 2 without being processed, the conductor is a simple internal layer conductor, which has an advantage to be manufactured easily. However, the internal layer conductors 6a and 6b in the rectangular shape inhibit the magnetic field generated at the spiral conductors and reduce efficiency. A shape that a part of the internal layer conductors 6a and 6b is trimmed as shown in FIG. 15 prevents reduction in efficiency.

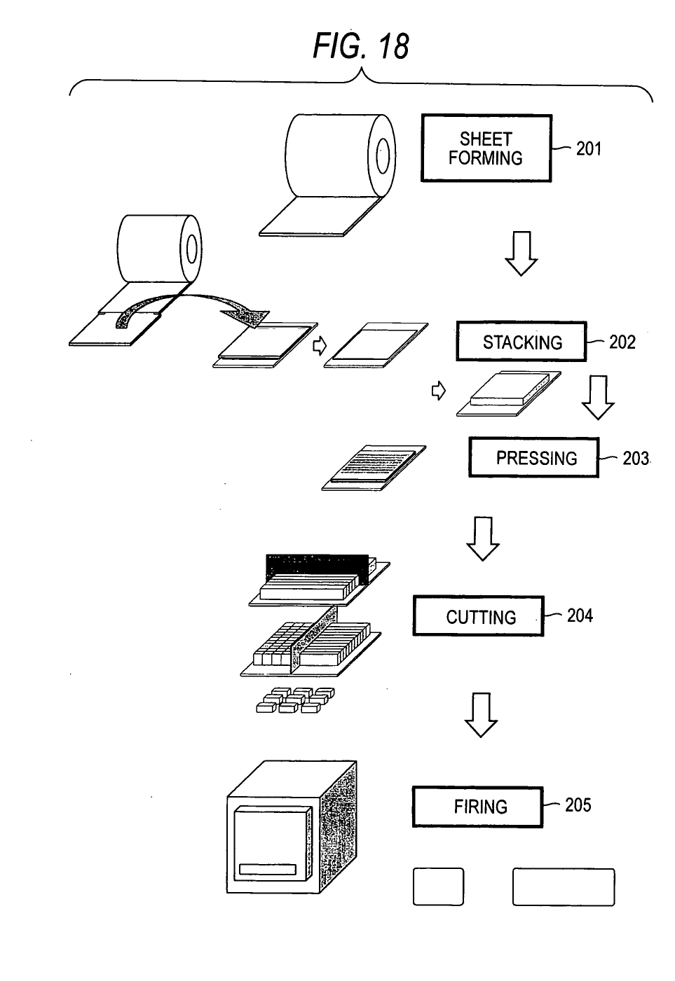

As shown in FIG. 16, only the connection film 8 is connected to the first terminal 5a, and only the connection film 9 is connected to the second terminal 5b. Both of the connection films 10a and 10b are connected to the third terminal 5c. The connection films 10a and 10b are provided in the center of the third terminal 5c, the center not comprising the spiral conductors 3a and 3b, the connection films not contacting each other. Parts of the base other than the connection films 10a, 10b, 8, and 9 are coated with the protective film 7 to protect the inside. The connection films 8, 9, 10a, and 10b are connected to wiring of another electronic circuit with solder. The protective film 7 is only absorbed when an absorption nozzle of a mounted device picks up the component because the connection film is separated into the connection films 10a and 10b. A pickup error is thus reduced.

A vertical length M1 is about 0.6 mm, a horizontal length M2 is about 0.8 mm, and a length M3 is about 1.6 mm as shown in FIG. 16 in the present embodiment. In the present embodiment, the connection films 10a and 10b are provided discretely over parts of a side wall with the length M1 and a side wall with the length M2. The surface of the mounted substrate is thus positioned to oppose the side wall with the width M2 in the component.

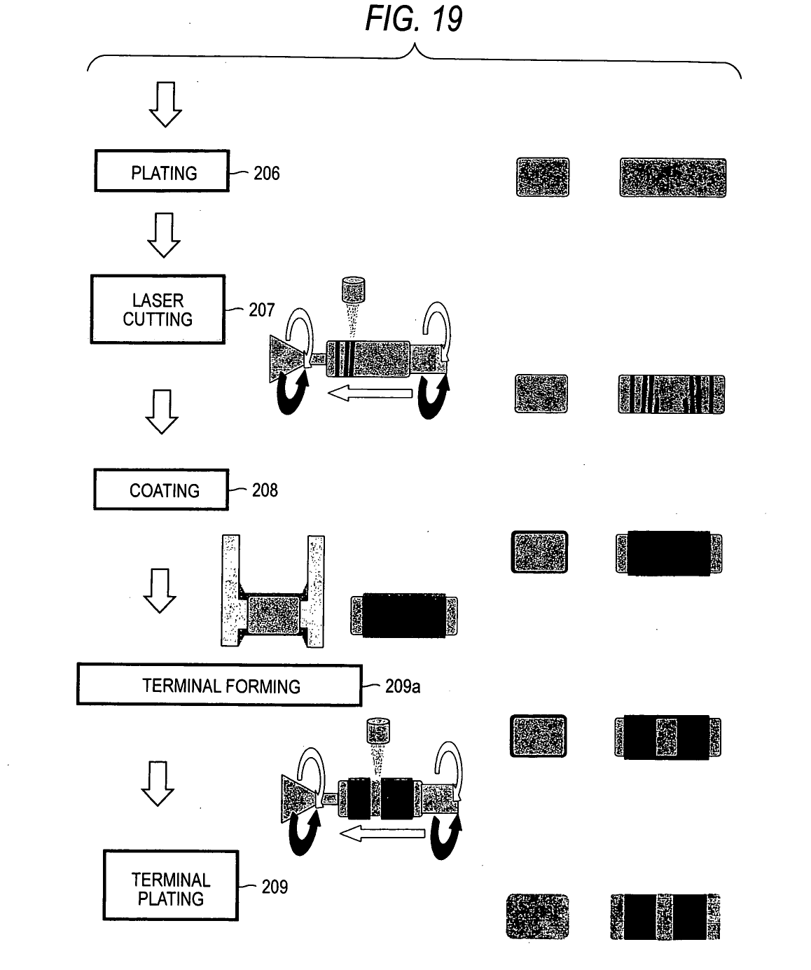

A manufacturing method will be described next with reference to FIGS. 17 to 19.

First, main ingredients of the component material of the base 2 (CaCO₃ contains 30 wt % to 50 wt %; Nb₂O₃, 30 wt % to 50 wt %; BaCO₃, 5 wt % to 15 wt %; and SiO₂, 5 wt % to 10 wt %) are mixed (S200). After that, the material is formed into a sheet (S201) as shown in FIG. 18. Next, the sheet-shaped element formed at Step 201 is cut into a predetermined shape to form a sheet-shaped piece. A conductor layer corresponding to one of the internal layer conductors is formed by printing or transfer at the first layer or the layer of a plural ordinal number of the sheet-shaped piece. After that, a plurality of other sheet-shaped pieces cut from the sheet-shaped element are further laminated. A conductor layer which becomes the other internal layer conductor is formed by printing or transfer on the lamination body. Another sheet-shaped piece is cut from the sheet-shaped body. The piece is laminated to be one or more layers. The laminated base is thus formed (S202).

Next, after pressing the laminated base with a predetermined pressure about 5 to 15 MPa (50 to 150 kg/cm²) (S203), a plurality of pole elements which become the base 2 are cut from the laminated base (S204). The cut pole elements are fired with a predetermined temperature of 900° C. to 960° C. (S205). The conductive film is formed on the entire surface of the cut pole elements by electroless plating or electronic plating to form the base 2 as shown in FIG. 19 (S206). While rotating the base 2, the conductive film which is unnecessary for the base 2 is eliminated by a pulsed laser such as a YAG laser to form the conductive film with the pattern shown in FIG. 1 and FIG. 14 (S207). The protective film made of resin is formed by electrodeposition coating by causing an electrode to contact only the third terminal (S208). The YAG laser irradiates the base to eliminate a portion of the protective film which forms the connection films 10a and 10b (S209a). The connection film is formed by forming at least a solder layer on a part other than the protective film as shown in FIG. 19(e) (S209). A characteristic and a size of each part are measured to check the component as to whether it conforms or is defective (S210).

The LC composite component of the present invention comprises a base, a first to third terminals provided on the base, a helical conductor provided on the base, and an internal layer conductor inside the base, the internal layer conductor being opposed to the helical conductor provided on the base, each of the first to third terminals being mutually and electrically noncontinuous, the helical conductor being provided in either position between the first to third terminals. A high-pass filter is thus realized. The component can be used for various devices that require a reduction in size and cost of the electronic device while ensuring the filter performance.

This application is based upon and claims the benefit of priority of Japanese Patent Application No. 2004-049664 filed on Feb. 25, 2004, the contents of which are incorporated herein by reference in its entirety.

1. An LC composite component comprising:
a base;
at least a first to third terminals provided on the base;
a helical conductor provided on the base; and
an internal layer conductor inside the base, the internal layer conductor being opposed to the helical conductor provided on the base,
wherein each of the first to third terminals does not contact each other, and
the helical conductor is provided in either position between the first to third terminals.

2. The LC composite component according to claim 1, wherein the first terminal and the second terminal are provided at both ends of the base, respectively.

3. The LC composite component according to claim 1, wherein the third terminal is provided between the first terminal and the second terminal.

4. The LC composite component according to claim 1, wherein the third terminal is provided about a center of the base.

5. The LC composite component according to claim 1, wherein a plurality of the helical conductors are provided between the first terminal and the second terminal.

6. The LC composite component according to claim 1, wherein the helical conductor is provided only between the first terminal and the third terminal or only between the second terminal and the third terminal.

7. The LC composite component according to claim 1, wherein the helical conductor is provided both between the first terminal and the third terminal and between the second terminal and the third terminal.

8. The LC composite component according to claim 1, wherein a plurality of the helical conductors are provided.

9. The LC composite component according to claim 1, wherein the helical conductor is provided in mirror symmetrical positions with reference to the third terminal.

10. The LC composite component according to claim 1, wherein the helical conductor is provided in rotational symmetrical positions with reference to the third terminal.

11. The LC composite component according to claim 1, wherein the first terminal and the second terminal form coupling capacitors with opposed sides.

12. The LC composite component according to claim 1, wherein the internal layer conductor forms a coupling capacitor with the opposed helical conductor.

13. The LC composite component according to claim 1, wherein the internal layer conductor is about parallel with a surface of the base comprising the opposed helical conductor.

14. The LC composite component according to claim 1, wherein the internal layer conductor is not electrically continuous with other parts.

15. The LC composite component according to claim 1, wherein a periphery of the base is covered with a conductive film of one of a single layer and a plurality of layers, and the helical conductor is formed by the conductive film being processed by one of etching or trimming or cutting.

16. The LC composite component according to claim 1, wherein the first terminal and the second terminal are constructed by forming gaps along the periphery of the base by performing one of etching or trimming or cutting to the conductive film of one of a single layer and a plurality of layers, the conductive film covering the periphery of the base.

17. The LC composite component according to claim 16, wherein the first terminal and the second terminal form coupling capacitors with opposed sides at the gaps.

18. The LC composite component according to claim 1, wherein lines forming the helical conductor generate a capacitor component between the lines in the helical conductor.

19. The LC composite component according to claim 18, wherein the capacitor component generated between the lines of the helical conductor is a capacitor component connected parallel to the helical conductor.

20. The LC composite component according to claim 1, wherein the periphery of the base is a straight structure having almost identical peripheries.

21. The LC composite component according to claim 1, wherein the periphery of the base has a layer down at a part other than the first to third terminals.

22. The LC composite component according to claim 1, wherein a shape of the base is one of a square pole, a cylinder, a triangle pole, and a polygon pole.

23. The LC composite component according to claim 1, wherein a protective film covering at least the helical conductor is provided on the base.

24. The LC composite component according to claim 23, wherein the protective film is made of one of a coating material and a tube-shaped resin.

25. The LC composite component according to claim 24, wherein the coating material contains at least one material selected from the group consisting of electrodeposition coating, transfer coating, glass, and low-temperature ceramics.

26. The LC composite component according to claim 1, wherein ceramics with a dielectric constant of 1 to 150 is used for a material of the base.

27. The LC composite component according to claim 1, wherein an inside independent conductor apart from the internal layer conductor is provided inside the base.

28. The LC composite component according to claim 27, wherein the inside independent conductor dampens magnetic flux that has occurred by the helical conductor.

29. The LC composite component according to claim 1, wherein the first terminal and the second terminal are connected to a signal line.

30. The LC composite component according to claim 1, wherein the third terminal is connected to a grounding part.

31. The LC composite component according to claim 1, wherein the LC component is a high-pass filter passing a signal in a high-frequency band.

32. A surface mounted component comprising:
an LC composite component comprising:
a base;
a first to third terminals provided on the base;
a helical conductor provided on the base; and
an internal layer conductor inside the base, the internal layer conductor being opposed to the helical conductor provided on the base,
wherein each of the first to third terminals does not contact each other, and
the helical conductor is provided in either position between the first to third terminals; and
a mounted substrate comprising a signal line and a grounding part, the mounted substrate being mounted with the LC composite component,
wherein the first terminal and the second terminal are electrically connected to the signal line, and the third terminal is connected to the grounding part.
